(19) United States
(12) Patent Application Publication
(10) Pub. No.: US 2013/0272822 A1
(43) Pub. Date: Oct. 17, 2013

(54) TRANSFER ROBOT

(71) Applicant: KABUSHIKI KAISHA YASKAWA DENKI, Kitayushu-shi (JP)

(72) Inventors: Nobuyuki FURUKAWA, Kitakyushu-shi (JP); Yuuki OHARA, Kitakyushu-shi (JP)

(21) Appl. No.: 13/647,672

(22) Filed: Oct. 9, 2012

(30) Foreign Application Priority Data
Dec. 19, 2011 (JP) 2011-277454
Dec. 20, 2011 (JP) 2011-278220

(51) Int. Cl. H01L 21/677

(52) U.S. Cl. CPC H01L 21/67739
USPC 414/217

(57) ABSTRACT

A transfer robot includes a first arm having a base end portion rotatably connected to an arm base, a second arm having a base end portion rotatably connected to a tip end portion of the first arm, and a hand having a hand base rotatably connected to a tip end portion of the second arm, the hand serving to hold a substrate. The first arm includes a specified drive system arranged therein, and the second arm is driven by the first arm. A reflector plate is arranged between the first arm and the second arm and configured to upwardly reflect heat coming from the substrate held on the hand.

### CROSS-REFERENCE TO RELATED APPLICATION

The present disclosure contains subject matter related to that disclosed in Japanese Priority Patent Application No. 2011-278220 filed with the Japan Patent Office on Dec. 20, 2011, the entire contents of which are incorporated herein by reference.

### BACKGROUND OF THE INVENTION

1. Field of the Invention

An embodiment disclosed herein relates to a transfer robot.

2. Description of the Related Art

Conventionally, there is available a transfer robot that transfers an unprocessed substrate or a processed substrate by use of an arm unit within a vacuum chamber for performing a film forming process or the like.

In case where the transfer robot is used to transfer, e.g., a substrate subjected to a film forming process, there is a possibility that the transfer robot may be heated by the hot substrate.

In this regard, there has been proposed a transfer robot that includes a radiator plate provided at a base end of an arm unit so as to radiate the heat transferred from a substrate through the arm unit by thermal conduction and a heat receiving plate provided in a specified position within a vacuum chamber in an opposing relationship with the radiator plate (see, e.g., International Patent Publication No. WO 06/062183).

With the aforementioned configuration, the heat coming from the substrate is sent back to the vacuum chamber so that heat energy should not be accumulated in the transfer robot.

However, the technology cited above is nothing but a technology in which the arm unit just receives heat from the substrate and sends the heat back to the vacuum chamber. In other words, in the conventional technology stated above, the arm unit cannot avoid reception of heat from the substrate.

If the arm unit receives heat from the substrate, there is a possibility that the arm unit may be expanded or the drive mechanism stored within the arm unit may be heated and expanded. This may possibly hinder accurate control of a robot.

### SUMMARY OF THE INVENTION

In accordance with an aspect of the present disclosure, there is provide a transfer robot, including: a first arm having a base end portion rotatably connected to an arm base, the first arm including a specified drive system arranged therein; a second arm having a base end portion rotatably connected to a tip end portion of the first arm, the second arm being driven by the first arm; a hand having a hand base rotatably connected to a tip end portion of the second arm, the hand serving to hold a substrate; and a reflector plate arranged between the first arm and the second arm and configured to upwardly reflect heat coming from the substrate held on the hand.

### BRIEF DESCRIPTION OF THE DRAWINGS

FIG. 1 is a schematic explanatory side section view showing a transfer robot according to an embodiment.

FIG. 2 is an explanatory plan view of the transfer robot.

FIG. 3 is a schematic explanatory plan view showing an internal structure of a first arm of the transfer robot.

FIG. 4 is a schematic explanatory vertical section view showing the internal structure of the first arm of the transfer robot.

### DESCRIPTION OF THE EMBODIMENTS

Hereinafter, an embodiment of a transfer robot disclosed herein will be described in detail with reference to the accompanying drawings which form a part hereof. However, the present disclosure is not limited to the embodiment to be described below.

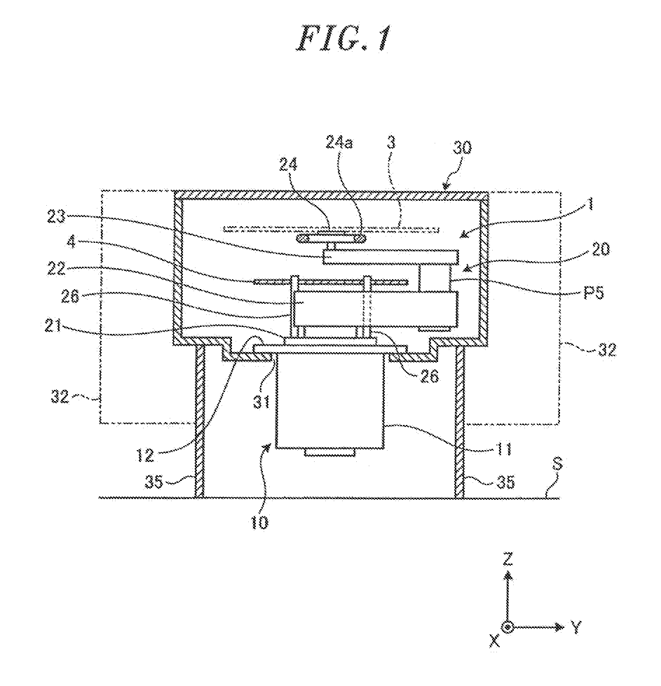

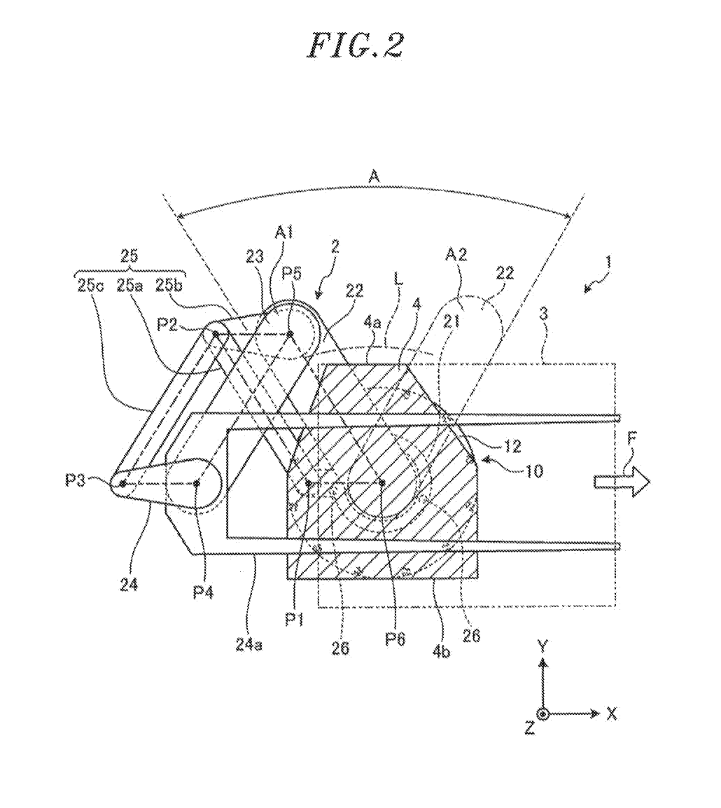

First, the schematic configuration of the transfer robot according to the present embodiment will be described with reference to FIGS. 1 and 2. FIG. 1 is a schematic explanatory side section view showing the transfer robot according to the present embodiment. FIG. 2 is an explanatory plan view of the transfer robot.

As shown in FIG. 1, the transfer robot 1 according to the present embodiment is a horizontal articulated robot that includes an arm unit 20 having two extendible arms capable of extending and retracting in the horizontal direction and a body unit 10 for supporting the arm unit 20. The transfer robot 1 is installed in a vacuum chamber 30. The vacuum chamber 30 is kept in a depressurized state by a vacuum pump or the like.

The body unit 10 is a unit provided below the arm unit 20 and makes up a robot body. The body unit 10 includes a housing 11 and a lifting device (not shown) accommodated in the housing 11. The body unit 10 is capable of moving the arm unit 20 up and down in the vertical direction through the use of the lifting device. The housing 11 of the body unit 10 protrudes downward from the vacuum chamber 30 and lies in a space defined within a support unit 35 which supports the vacuum chamber 30.

The lifting device arranged within the housing 11 of the body unit 10 is configured to include, e.g., a motor, a ball screw and a ball nut. The lifting device moves the arm unit 20 up and down by converting rotational movement of the motor to linear movement.

A flange 12 is formed in the upper portion of the housing 11. The transfer robot 1 is installed in the vacuum chamber 30 by fixing the flange 12 to the vacuum chamber 30. The flange 12 is fixed through a seal member to an edge portion of an opening 31 formed in the bottom portion of the vacuum chamber 30.

The arm unit 20 is a unit connected to the body unit 10 as a robot body. The arm unit 20 includes an arm base 21, a first arm 22, a second arm 23 and a hand base 24. A fork-shape hand 24a as an end effector capable of holding a substrate 3 such as a glass substrate or a semiconductor wafer (hereinafter sometimes referred to as “workpiece”) is mounted to the hand base 24.

In the following description, the advance-retreat direction of the hand 24a in FIG. 2 will be referred to as “X-axis direction”. The direction horizontally orthogonal to the X-axis direction will be referred to as “Y-axis direction”. The direction orthogonal to the X-axis direction and the Y-axis direction, i.e., the vertical direction, will be referred to as “Z-axis direction”.

In describing the relative positional relationship between the respective components of the transfer robot 1, the directions will sometimes be designated by an up-down direction, a left right direction and a front-rear direction. The respective directions will be defined on the assumption that the transfer robot 1 is installed on a horizontal installation surface S. More specifically, the positive and negative sides of the X-axis direction in FIGS. 1 and 2 will be referred to as front and rear sides of the transfer robot I. The positive and negative sides of the Y-axis direction in FIGS. 1 and 2 will be referred to as right and left sides of the transfer robot 1. The positive and negative sides of the Z-axis direction in FIGS. 1 and 2 will be referred to as upper and lower sides of the transfer robot 1.

The arm base 21 is rotatably supported with respect to a lifting flange not shown. The lifting flange is operatively connected to the lifting device provided within the body unit 10. The arm base 21 includes a swing device made up of a motor and a speed reducer. The arm base 21 rotates, namely revolves on its own axis using the swing device.

More specifically, the swing device is configured such that the rotation of a motor is inputted via a transmission belt to a speed reducer whose output shaft is fixed to the body unit 10. Thus the arm base 21 horizontally revolves on its own axis using the output shaft of the speed reducer as a swing axis. This makes it possible to have the hand 24a directly face a plurality of processing chambers 32 or the like provided around the vacuum chamber 30.

The base end portion of the first arm 22 is rotatably connected to the upper portion of the arm base 21. In other words, a connecting axis P6 of the arm base 21 is integrally connected to an input shaft 510 of a first speed reducer 51 provided in the base end portion of the first arm 22 (see FIG. 4). The first arm 22 is rotatably connected to the arm base 21 by way of the first speed reducer 51.

The base end portion of the second arm 23 is rotatably connected to the tip end upper portion of the first arm 22. In other words, a base end connecting axis P5 of the second arm 23 and an input shaft 520 of a second speed reducer 52 provided in the tip end portion of the first arm 22 are integrally connected to each other via a connecting plate 522 (see FIG. 4). The second arm 23 is rotatably connected to the first arm 22 through the second speed reducer 52.

The transfer robot 1 is configured to synchronously operate the first speed reducer 51 provided in the base end portion of the first arm 22 and the second speed reducer 52 provided in the tip end portion of the first arm 22, through the use of a single motor 53. The transfer robot 1 can linearly move the tip end of the second arm 23 having no drive system and serving as a link.

In other words, the transfer robot 1 includes: the first arm 22 having a base end portion rotatably connected to the arm base 21 and a specified drive system installed therein; and the second arm 23 having a base end portion rotatably connected to the tip end portion of the first arm 22, the second arm 23 being driven by the first arm 22. That is to say, the second arm 23 is not provided with its own drive system while the first arm 22 is provided therein with the motor 53, the first speed reducer 51 and the second speed reducer 52 as a drive system.

The transfer robot 1 is designed such that the rotation amount of the second arm 23 with respect to the first arm 22 is twice as large as the rotation amount of the first arm 22 with respect to the arm base 21. For example, the first arm 22 and the second arm 23 are rotated such that, if the first arm 22 rotates α degrees with respect to the arm base 21, the second arm 23 rotates 2α degrees with respect to the first arm 22. Accordingly, the tip end portion of the second arm 23 is moved linearly.

With a view to prevent contamination of the inside of the vacuum chamber 30, the drive devices such as the first speed reducer 51, the second speed reducer 52 and the motor are arranged within the first arm 22 kept at the atmospheric pressure. Therefore, even if the transfer robot 1 is kept under a depressurized environment, e.g., within the vacuum chamber 30, it is possible to prevent a lubricant such as grease or the like from getting dry and to prevent the inside of the vacuum chamber 30 from being contaminated by dirt.

The hand base 24 is rotatably connected to the tip end upper portion of the second arm 23. The hand base 24 is a member that moves in response to the rotating operation of the first arm 22 and the second arm 23. The hand 24a for holding the substrate 3 is provided in the upper portion of the hand base 24.

While not shown in FIG. 1, the arm unit 20 includes an auxiliary arm portion 25 making up a link mechanism as shown in FIG. 2. The arm unit 20 will now be described in more detail with respect to FIG. 2.

The auxiliary arm portion 25 making up the link mechanism restrains rotation of the hand base 24 in conjunction with the rotating operation of the first arm 22 and the second arm 23 so that the hand 24a can always face a specified direction during its movement.

In other words, as shown in FIG. 2, the auxiliary arm portion 25 includes a first link 25a, an intermediate link 25b and a second link 25c.

The base end portion of the first link 25a is rotatably connected to the arm base 21 through a pivot axis P1. The tip end portion of the first link 25a as rotatably connected to the tip end portion of the intermediate link 25b and the base end portion of the second link 25c through a pivot axis P2. The base end portion of the intermediate link 25b is pivoted in a coaxial relationship with a base end connecting axis P5 interconnecting the first arm 22 and the second arm 23. The tip end portion of the intermediate link 25b is rotatably connected to the tip end portion of the first link 25a and the base end portion of the second link 25c through the pivot axis P2.

The base end portion of the second link 25c is rotatably connected to the tip end portion of the intermediate link 25b through the pivot axis P2. The Lip end portion of the second link 25c is rotatably connected to the base end portion of the hand base 24 through a pivot axis P3. The tip end portion of the hand base 24 is rotatably connected to the tip end portion of the second arm 23 through a pivot axis P4. The base end portion of the hand base 24 is rotatably connected to the tip end portion of the second link 25c through the pivot axis P3.

In this manner, the first link 25a, the arm base 21 and the intermediate link 25b make up a first parallel link mechanism (P1-P6-P5-P2). In other words, if the first arm 22 rotates about the connecting axis P6, the first link 25a rotates while keeping parallelism with the first arm 22. The connecting line interconnecting the connecting axis P6 and the connecting axis P1 rotates while keeping parallelism with the intermediate link 25b.

The second link 25c, the intermediate link 25b, the second arm 23 and the hand base 24 make up a second parallel link mechanism (P2-P5-P4-P3). In other words, if the second arm 23 rotates about the base end connecting axis P5, the second link 25c and the hand base 24 rotate while keeping parallelism with the second arm 23 and the intermediate link 25b, respectively.

The intermediate link 25b rotates while keeping parallelism with the aforementioned connecting line under the action of the first parallel link mechanism. For that reason, the hand base 24 of the second parallel link mechanism rotates while keeping parallelism with the arm base 21. As a result, the hand 24a mounted to the upper portion of the hand base 24 moves linearly while keeping parallelism with the aforementioned connecting line.

In this manner, the transfer robot 1 can maintain the orientation of the hand 24a constant using two parallel link mechanisms, i.e., the first parallel link mechanism and the second parallel link mechanism. Therefore, as compared with, e.g., a case where pulleys and transmission belts are provided within the second arm 23 to maintain constant the orientation of an end effector corresponding to the hand 24a, it is possible to reduce generation of dirt attributable to the pulleys and the transmission belts. Inasmuch as the rigidity of the arm as a whole can be increased by the auxiliary arm portion 25, it is possible to reduce vibrations during the operation of the hand 24a.

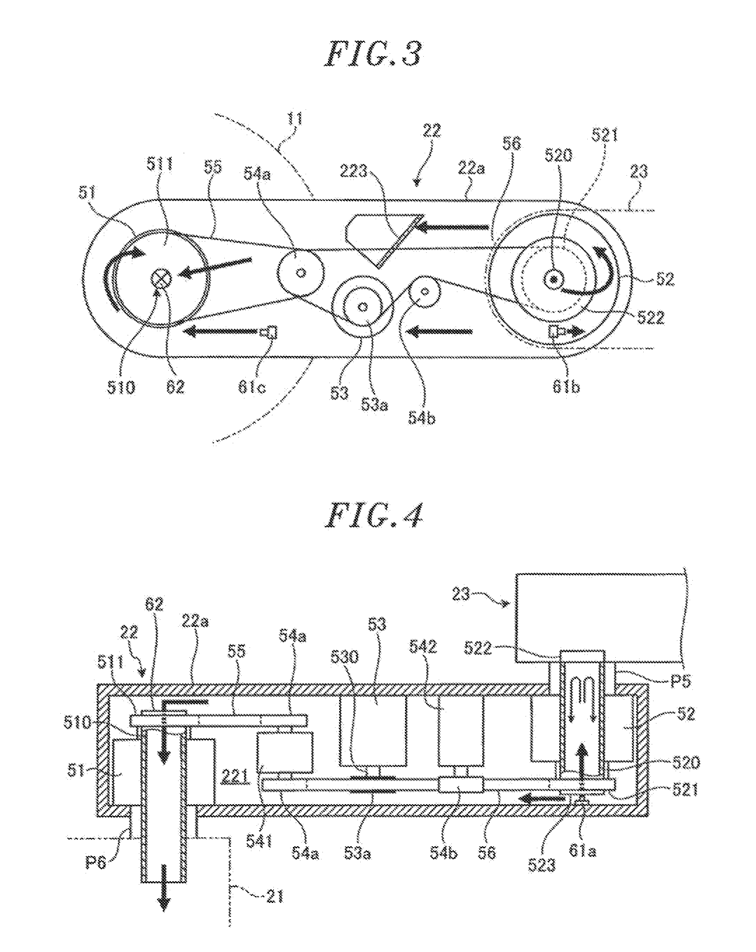

FIG. 3 is a schematic explanatory plan view showing the internal structure of the first arm 22 of the transfer robot 1. FIG. 4 is a schematic explanatory vertical section view of the first arm 22. As shown in FIGS. 3 and 4, the inside of an arm housing 22a making up the first arm 22 defines a box-shaped storage portion 221 kept at the atmospheric pressure. A drive system including, e.g., a first speed reducer 51, a second speed reducer 52, a motor 53, first relay pulleys 54a, a second relay pulley 54b, a first transmission belt 55 and a second transmission belt 56 is provided within the storage portion 221. As shown in FIG. 4, the first relay pulleys 54a are arranged above and below a pulley support body 541.

The first speed reducer 51 is arranged in the base end portion of the first arm 22 and is configured to rotatably interconnect the arm base 21 and the first arm 22 through the connecting axis P6. The second speed reducer 52 is arranged in the tip end portion of the first arm 22 and is configured to rotatably interconnect the first arm 22 and the second arm 23 through the base end connecting axis P5.

The motor 53 is a drive unit for generating drive power and is arranged substantially in the central region of the first arm 22. The relay pulleys 54a and 54b are rotatably mounted to shafts arranged parallel to the output shaft 530 of the motor 53. The relay pulleys 54a and 54b are arranged side by side with the motor 53 interposed therebetween.

The first transmission belt 55 transmits the drive power of the motor 53 to the input shaft 510 of the first speed reducer 51. The second transmission belt 56 transmits the drive power of the motor 53 to the input shaft 520 of the second speed reducer 52.

As shown in FIGS. 3 and 4, the first transmission belt 55 is wound around the first pulley 511 fixed to the input shaft 510 of the first speed reducer 51 and around one of the first relay pulleys 54a. The second transmission belt 56 is wound around the second pulley 521 fixed to the input shaft 520 of the second speed reducer 52, the driving pulley 53a fixed to the output shaft 530 of the motor 53, the first relay pulley 54a positioned at the lower side and the second relay pulley 54b arranged at the lower side of the pulley support body 542. Accordingly, the drive power of the motor 53 transmitted from the second transmission belt 56 through the first relay pulleys 54a is transmitted to the input shaft 510 of the first speed reducer 51 by the first transmission belt 55.

In this manner, the transfer robot 1 can synchronously operate the first arm 22 and the second arm 23 by transmitting the drive power of the single motor 53 to the first speed reducer 51 and the second speed reducer 52 through the use of the first transmission belt 55 and the second transmission belt 56.

In the transfer robot 1, the respective members making up the drive system are arranged in the storage portion 221 of the first arm 22 kept in the atmospheric pressure. It is therefore possible to prevent a lubricant of the drive system such as grease or the like from getting dry and to prevent the inside of the vacuum chamber 30 from being contaminated by dirt.

As set forth above, the transfer robot 1 according to the present embodiment can take out the substrate 3 from another vacuum chamber connected to the vacuum chamber 30 by, e.g., linearly moving the hand 24a through the use of the first arm 22 and the second arm 23.

Subsequently, the transfer robot 1 returns the hand 24a back and then rotates the arm base 21 about the swing axis, thereby causing the arm unit 20 to directly face another vacuum chamber as the transfer destination of the workpiece. Then, the transfer robot 1 linearly moves the hand 24a through the use of the first arm 22 and the second arm 23, thereby loading the workpiece into another vacuum chamber as the transfer destination of the workpiece. In this manner, the transfer robot 1 can transfer the substrate 3 within the vacuum chamber 30.

In the transfer robot 1 according to the present embodiment, a reflector plate 4 for upwardly reflecting the heat coming from the substrate 3 placed on the hand 24a is provided between the first arm 22 and the second arm 23.

Detailed description will now be made on the reflector plate 4. As set forth above, the transfer robot 1 according to the present embodiment is installed within the vacuum chamber 30. In case of transferring, e.g., a substrate 3 subjected to a film forming process, the substrate 3 remains hot. In a state that, as shown in FIGS. 1 and 2, the hand. 24a comes back to the rearmost position (the left position in FIG. 2) along the transfer direction F, the first arm 22 and the body unit 10 are positioned just below the substrate 3.

The posture of the transfer robot 1 assumed when the hand 24a comes back to the rearmost position is a minimum swing posture. The rotation radius about the connecting axis P6 of the arm base 21 as the swing axis becomes smallest in the minimum swing posture.

If the transfer robot 1 assumes the minimum swing posture in this manner, there is a possibility that the first arm 22 and the body unit 10 positioned just below the substrate 3 are heated by the radiant heat coming from the substrate 3. It is presumed that the substrate 3 has a temperature of from about 100° C. to about 130° C.

In particular, as stated above, the drive system including, e.g., the first speed reducer 51, the second speed reducer 52, the motor 53, the first relay pulleys 54a, the second relay pulley 54b, the first transmission belt 55 and the second transmission belt 56 is arranged within the arm housing 22a of the first arm 22. These components may be adversely affected when heated.

In the present embodiment, the reflector plate 4 is arranged above the first arm 22 and below the second arm 23 to upwardly reflect the radiant heat coming from the substrate 3. This restrains the first arm 22 and the body unit 10 from being heated by the radiant heat.

As shown in FIGS. 1 and 2, the reflector plate 4 is supported by a plurality of (two, in the present embodiment) pins 26 installed upright on the arm base 21 so that they can be positioned outside the swing region A of the first arm 22.

Therefore, the reflector plate 4 swings together with the first arm 22 fixed to the arm base 21. The relative positional relationship between the reflector plate 4 and the swing region A of the first arm 22 becomes constant.

Description will now be made on the swing region A of the first arm 22. When the transfer robot 1 linearly moves the hand 24a from the position shown in FIG. 2 toward the front side (in the X-axis direction), the first arm 22 swings clockwise about the connecting axis P6 of the first arm 22 and moves to a:position (indicated by a single-dot chain line in FIG. 2) which is line-symmetric with respect to the position in FIG. 2. Since the first arm 22 has a specified width when seen in a plan view, the swing region A of the first arm 22 according to the present embodiment is the region between the initial position A1 of the rear outer edge of the first arm 22 and the moved position A2 of the front outer edge of the first arm 22.

This means that the pins 26 cannot be arranged inside the swing region A of the first arm 22. The number of the pins 26 may be appropriately set insofar as the pins 26 are installed outside the swing region A of the first arm 22.

As shown in FIG. 1, the pins 26 have a height set larger than the thickness of the first arm 22. The pins 26 hold the reflector plate 4 between the first arm 22 and the second arm 23. In the present embodiment, the reflector plate 4 is held in place by fitting the pins 26 to the connecting holes of the reflector plate 4. However, the connecting structure of the pins 26 is not particularly limited. It goes without saying that the height of the upper ends of the pins 26 is set not to interfere with the second arm 23.

As shown in FIG. 2, the reflector plate 4 is formed into such a shape that the reflector plate 4 can cover at least a portion of the first arm 22 within which the drive system is accommodated. In the present embodiment, the reflector plate 4 is shaped to cover the upper surface of the body unit 10 having the arm base 21 to which the first arm 22 is rotatably connected.

One reason is that the lifting mechanism for lifting and lowering the arm unit 20 including the first arm 22 and the second arm 23 is arranged within the body unit 10. Another reason is that the body unit 10 needs to be kept at a low temperature as far as possible so that the heat can be dissipated through the body unit 10 even when the first arm 22 is heated.

The specific shape of the reflector plate 4 may be just a rectangular shape or a circular shape. In order to reduce the weight of the reflector plate 4, it is desirable that the reflector plate 4 be formed by cutting away unnecessary portions. In the present embodiment, as shown in FIG. 2, the reflector plate 4 is formed into a substantially rectangular shape with the front and rear corner portions of the right side (the Y-axis positive side in FIG. 2) cut away.

The reflector plate 4 is arranged so as not to interfere with the moving trajectory of the connecting portion interconnecting the first arm 22 and the second arm 23, namely the moving trajectory L of the inner end of the connecting portion.

In other words, the base end connecting axis P5 (see FIG. 4) that forms the connecting portion interconnecting the first arm 22 and the second arm 23 is moved toward the front side of the transfer robot 1 (toward the X-axis positive side in FIG. 2) while swinging about the connecting axis P6.

The edge of the reflector plate 4 facing toward the right side of the transfer robot 1 (the upper edge 4a of the reflector plate 4 in FIG. 2) is positioned so as not to interfere with the inner end of the connecting portion, i.e., the moving trajectory L of the left circumferential surface of the base end connecting axis P5. On the other hand, the edge of the reflector plate 4 facing toward the left side of the transfer robot 1 (the lower edge 4b of the reflector plate 4 in FIG. 2) is positioned so as to substantially overlap with the left circumferential surface of the body unit 10. Accordingly, the transverse width of the reflector plate 4 (the Y-axis direction width in FIG. 2) is defined.

In order for the reflector plate 4 to cover the substantially entire surface of the body unit 10, the length of the reflector plate 4 in the front-rear direction (the X-axis direction in FIG. 2) is set substantially equal to the diameter of the body unit 10. This also means that the length of the reflector plate 4 is equal to the diameter of the flange 12 formed in the upper portion of the housing 11 of the body unit 10.

The shape and arrangement of the reflector plate 4 according to the present embodiment is defined in the manner stated above. However, the shape and arrangement of the reflector plate 4 may be arbitrarily set as long as the reflector plate 4 does not interfere with the moving trajectory L of the connecting portion interconnecting the first arm 22 and the second arm 23 and can cover at least a portion of the first arm 22.

As described above, the reflector plate 4 is provided to upwardly reflect the radiant heat coming from the substrate 3 placed on the hand 24a, thereby reducing the influence of the radiant heat on the first arm 22 as far as possible. However, there may be such a situation that the first arm 22 is heated to a high temperature in the long run.

In the present embodiment, as shown in FIGS. 3 and 4, a plurality of air injection holes 61a through 61c and a single air exhaust hole 62 are provided within the arm housing 22a of the first arm 22, namely in the box-shaped storage portion 221 kept at the atmospheric pressure. The compressed air injected from the air injection holes 61a through 61c flows along the inner wall surface of the arm housing 22a. Then, the injected air is discharged from the air exhaust hole 62.

In the present embodiment, the first input shaft 510 of the first speed reducer 51 arranged at one end of the arm housing 22a is formed into a hollow shaft which serves as the air exhaust hole 62.

The second input shaft 520 of the second speed reducer 52 arranged at the other end of the arm housing 22a is formed into a hollow shaft. One of the air injection holes 61a through 61c, e.g., the first air injection hole 61a, is installed near the base end opening 523 of the second input shaft 520 as a hollow shaft.

The compressed air injected from the first air injection hole 61a into the second input shaft 520 flows upward and impinges against the connecting plate 522. The compressed air is reflected by the connecting plate 522 and is discharged from the base end opening 523 into the storage portion 221. The compressed air supplied from the first air injection hole 61a flows along the inner wall surface of the arm housing 22a and deprives the arm housing 22a of heat until the compressed air is discharged to the outside from the air exhaust hole 62 formed in the first input shaft 510 as a hollow shaft.

On the other hand, the remaining air injection holes 61b and 61c are arranged so as to horizontally inject the compressed air along the side surface of the arm housing 22a.

For example, as shown in FIG. 3, the second air injection hole 61b is arranged between the second speed reducer 52 and the longitudinal side surface of the arm housing 22a so that the second air injection hole 61b can inject the compressed air toward the other end of the arm housing 22a. The compressed air injected from the second air injection hole 61b flows across the inside of the storage portion 221 and goes toward the air exhaust hole 62. During this time, the compressed air flows along the inner wall surface of the arm housing 22a and deprives the arm housing 22a of heat.

The third air injection hole 61c is arranged adjacent to the longitudinal side surface of the arm housing 22a between the first speed reducer 51 and the motor 53 so that the third air injection hole 61c can inject the compressed air toward one end of the arm housing 22a.

In this manner, the stream of the compressed air injected from the air injection holes 61a through 61c flows in random directions within the storage portion 221, i.e., within the arm housing 22a. Until the compressed air is discharged from the air exhaust hole 62 to the outside, the compressed air can take heat from the wide region extending over the substantially whole portion of the arm housing 22a and can cool the arm housing 22a.

In the transfer robot 1 according to the present embodiment, the arm housing 22a of the first arm 22 includes the drive system arranged therein. In contrast, the second arm 23 does not include any drive system and serves as a portion of the link being driven by the first arm 22. The inner wall surface of the arm housing 22a can be cooled by injecting the compressed air from the air injection holes 61a through 61c arranged within the arm housing 22a of the first arm 22.

In this manner, the transfer robot 1 according to the present embodiment can broadly cool the arm housing 22a. Since the inside of the first arm 22 is broadly cooled, it becomes possible to efficiently reduce accumulation of heat even if the first arm 22 is heated by the radiant heat coming from the substrate 3 held in the hand 24a.

A fin 223 joined to the arm housing 22a is arranged within the arm housing 22a so that the fin 223 can be exposed to the compressed air. That is to say, the heat of the arm housing 22a can be efficiently deprived through the fin 223.

In the present embodiment, as shown in FIG. 3, the fin 223 is positioned in an opposing relationship with the motor 53. The base end portion of the fin 223 is joined to the longitudinal side surface of the arm housing 22a. The fin 223 obliquely extends toward the motor 53. In the aforementioned position, the fin 223 is arranged to obliquely go across the air stream flowing along the flow path of the compressed air, namely along the longitudinal side surface of the arm housing 22a.

Accordingly, the fin 223 does not become a significant resistance against the stream of the compressed air. The compressed air can make contact with the entire surface of the fin 223. This makes it possible to increase the heat exchange rate.

The arrangement of the air injection holes 61a through 61c is not limited to the embodiment described above but may be set appropriately. The shape and arrangement of the fin 223 can be appropriately designed in light of the heat exchange rate or the like.

In the embodiment described above, the transfer robot 1 has been described as being a single-arm robot provided with one arm unit 20. Alternatively, the transfer robot 1 may be a double-arm robot or a robot provided with a plurality of arm units.

Briefly, the transfer robot 1 may have any configuration as long as it includes the first arm 22 having a specified drive system arranged therein, the second arm 23 rotatably connected to the first arm 22, and the reflector plate 4 arranged between the first arm 22 and the second arm and configured to reflect the heat coming from the substrate 3 placed on the hand 24a.

In the embodiment described above, the workpiece to be transferred has been described as being the substrate 3 such as a glass substrate or a semiconductor wafer. Alternatively, the target object to be transferred may not be the substrate 3 but may be other workpieces that can become relatively hot.

In the embodiment described above, description has been made on an instance where the transfer robot 1 is installed within the vacuum chamber 30. However, the arrangement place of the transfer robot 1 is not necessarily limited to the vacuum chamber 30.

Other effects and other modified examples can be readily derived by those skilled in the art. For that reason, the broad aspect of the present disclosure is not limited to the specific disclosure and the representative embodiment shown and described above. Accordingly, the present disclosure can be modified in many different forms without departing from the spirit and scope defined by the appended claims and the equivalents thereof.

What is claimed is:

1. A transfer robot, comprising:
a first arm having a base end portion rotatably connected to an arm base, the first arm including a specified drive system arranged therein;
a second arm having a base end portion rotatably connected to a tip end portion of the first arm, the second arm being driven by the first arm;
a hand having a hand base rotatably connected to a tip end portion of the second arm, the hand serving to hold a substrate; and
a reflector plate arranged between the first arm and the second arm and configured to upwardly reflect heat coming from the substrate held on the hand.

2. The robot of claim 1, further comprising:
an intermediate link having a base end portion supported in a coaxial relationship with a connecting axis interconnecting the first arm and the second arm;
a first link having a tip end portion rotatably connected to a tip end portion of the intermediate link and a base end portion rotatably connected to the arm base, the first link making up a first parallel link mechanism in cooperation with the arm base, the first arm and the intermediate link; and
a second link having a base end portion rotatably connected to the tip end portion of the intermediate link and a tip end portion rotatably connected to a base end portion of the hand base, the second link making up a second parallel link mechanism in cooperation with the second arm, the intermediate link and the hand base,
wherein the hand is configured to linearly move in conjunction with swing motion of the first arm and the second arm has no drive system.

3. The robot of claim 1, wherein the reflector plate is arranged in a position where the reflector plate does not interfere with a moving trajectory of a connecting portion interconnecting the first arm and the second arm.

4. The robot of claim 1, wherein the reflector plate is shaped to cover at least a portion of the first arm.

5. The robot of claim 4, wherein the reflector plate is shaped to cover an upper surface of a robot body in which the arm base is rotatably provided.

6. The robot of claim 1, wherein the reflector plate is supported by a plurality of pins installed upright on the arm base and positioned outside a swing region of the first arm.
